(19) United States
(12) Patent Application Publication
(10) Pub. No.: US 2014/0336498 A1
(43) Pub. Date: Nov. 13, 2014

(54) MEDICAL IMAGING SYSTEM HAVING A MAGNETIC RESONANCE IMAGING UNIT AND A POSITRON EMISSION TOMOGRAPHY UNIT

(71) Applicant: SIEMENS AKTIENGESELLSCHAFT, MUNICH (DE)

(72) Inventors: Matthias FENCHEL, Erlangen (DE); Bjorn HEISMANN, Erlangen (DE); Kirstin JATTKE, Nuremberg (DE); Ralf LADEBECK, Erlangen (DE); Sebastian SCHMIDT, Weisendorf (DE)

(73) Assignee: SIEMENS AKTIENGESELLSCHAFT, MUNICH (DE)

(21) Appl. No.: 14/264,191

(22) Filed: Apr. 29, 2014

(30) Foreign Application Priority Data
May 10, 2013 (DE) 102013208620.2

(51) Int. Cl. G01R 33/48

(52) U.S. Cl. CPC G01R 33/481; G01R 33/34
USPC 600/411

(57) ABSTRACT

A medical imaging system includes a magnetic resonance imaging unit including a magnet unit and a patient receiving area surrounded by the magnet unit, wherein the magnet unit includes a main magnet, a gradient coil unit and a radio-frequency antenna unit. In at least one embodiment, the medical imaging system further includes a positron emission tomography unit including at least two positron emission tomography detector modules. The at least two positron emission tomography detector modules each include a detector surface. Further, the radio-frequency antenna unit is disposed outside an area disposed between an examination area and the detector surfaces.

### PRIORITY STATEMENT

The present application hereby claims priority under 35 U.S.C. §119 to German patent application number DE 102013208620.2 filed May 10, 2013, the entire contents of which are hereby incorporated herein by reference.

### FIELD

At least one embodiment of the present invention generally relates to a medical imaging system having a Magnetic Resonance Imaging unit having a magnet unit and a patient receiving unit surrounded by the magnet unit, wherein the magnet unit comprises a main magnet, a gradient coil unit and a radio frequency antenna unit, and/or having a Positron Emission Tomography unit, wherein the Positron Emission Tomography unit has at least two Positron Emission Tomography detector modules.

### BACKGROUND

In medical imaging systems having a Magnetic Resonance Imaging unit and a Positron Emission Tomography unit (PET unit), magnetic resonance image data is often captured by way of a local radio frequency antenna unit. This local radio frequency antenna unit is preferably disposed around a subarea of the patient to be examined, such as for example a local head antenna unit around the patient's head and/or a local body antenna unit around a torso area of the patient etc. During a PET examination this local radio frequency antenna unit is disposed within a Field of View (FOV), especially between the subarea to be examined and a detection surface of the PET unit. However this arrangement of the local radio frequency antenna unit causes an attenuation of PET signals, wherein the PET signals will be attenuated as a result of material properties and/or a material thickness of the local radio frequency antenna unit.

Since a position of the local radio frequency antenna unit varies for different imaging examinations, it is difficult to detect this attenuation of the PET signals for a PET measurement correctly and take account of it during an evaluation of the PET image data. Furthermore a complexity of an examination sequence increases by way of the local radio frequency antenna units for the pending hybrid imaging examination, which comprises a PET examination and a magnetic resonance examination, since the local radio frequency antenna unit must also be positioned on the patient before the medical imaging examination.

To rectify these problems it is possible to dispense with the use of local radio frequency antenna units during a hybrid imaging examination, however, by doing so, the quality of the magnetic resonance images is significantly worsened. Furthermore the duration of any examination is increased by doing so, since no parallel data acquisition is possible.

### SUMMARY

At least one embodiment of the present invention is especially to minimize an attenuation of PET signals because of a radio frequency antenna unit. Advantageous embodiments are described in the dependent claims.

At least one embodiment of the invention is based on a medical imaging system having a Magnetic Resonance Imaging unit comprising a magnet unit and a patient receiving area surrounded by the magnet unit, wherein the magnet unit comprises a main magnet, a gradient coil unit and a radio frequency antenna unit, and having a Positron Emission Tomography unit, wherein the Positron Emission Tomography unit has at least two Positron Emission Tomography detector modules.

It is proposed in at least one embodiment that the at least two Positron Emission Tomography detector modules each have a detector surface and the radio frequency antenna unit is disposed outside a region between an examination area and the detector surfaces. In this context an examination region is to be understood especially as a region which comprises a Field of View (FOV) of the Positron Emission Tomography unit and/or a subarea of the patient to be examined in an examination position within a patient receiving area of the medical imaging system. Furthermore the term outside a region disposed between an examination region and the detector surfaces is especially to be understood as a region which is disposed outside an FOV of the Positron Emission Tomography unit, especially outside an FOV of the least to detector modules and/or is disposed outside the patient receiving area.

The inventive embodiment and/or arrangement of the radio frequency antenna unit advantageously enables an undesired attenuation of PET signals during data acquisition to be minimized and/or prevented. Furthermore in this way an especially space-saving and especially compact arrangement of the radio frequency antenna unit together with the PET unit can be achieved. Advantageously in this case the radio frequency antenna unit is disposed in an area adjoining the Positron Emission Tomography detector module, so that an essentially equal and/or overlapping field of view between the radio frequency antenna unit and the Positron Emission Tomography detector module can be achieved. Preferably the radio frequency antenna unit here comprises a radio frequency antenna receive unit which is integrated and/or disposed permanently within the Positron Emission Tomography unit. In this way a position of the radio frequency antenna unit, especially of the radio frequency antenna receive unit, is determined outside a field of view of the Positron Emission Tomography unit.

### BRIEF DESCRIPTION OF THE DRAWINGS

Further advantages, features and details of the invention emerge from the example embodiments described below and also with reference to the drawings.

In the figures:

FIG. 1 shows an embodiment of an inventive medical imaging system in a schematic diagram,

FIG. 2 shows a detailed view of a Positron Emission Tomography unit together with a radio frequency antenna unit of the medical imaging system,

FIG. 3 shows an alternate embodiment of the medical imaging system to FIG. 1 and

FIG. 4 shows a detailed view of a further example embodiment of a Positron Emission Tomography unit together with a radio frequency antenna unit of the medical imaging system.

### DETAILED DESCRIPTION OF THE EXAMPLE EMBODIMENTS

Various example embodiments will now be described more fully with reference to the accompanying drawings in which only some example embodiments are shown. Specific structural and functional details disclosed herein are merely representative for purposes of describing example embodiments. The present invention, however, may be embodied in many alternate forms and should not be construed as limited to only the example embodiments set forth herein.

Accordingly, while example embodiments of the invention are capable of various modifications and alternative forms, embodiments thereof are shown by way of example in the drawings and will herein be described in detail. It should be understood, however, that there is no intent to limit example embodiments of the present invention to the particular forms disclosed. On the contrary, example embodiments are to cover all modifications, equivalents, and alternatives falling within the scope of the invention. Like numbers refer to like elements throughout the description of the figures.

Before discussing example embodiments in more detail, it is noted that some example embodiments are described as processes or methods depicted as flowcharts. Although the flowcharts describe the operations as sequential processes, many of the operations may be performed in parallel, concurrently or simultaneously. In addition, the order of operations may be re-arranged. The processes may be terminated when their operations are completed, but may also have additional steps not included in the figure. The processes may correspond to methods, functions, procedures, subroutines, subprograms, etc.

Methods discussed below, some of which are illustrated by the flow charts, may be implemented by hardware, software, firmware, middleware, microcode, hardware description languages, or any combination thereof. When implemented in software, firmware, middleware or microcode, the program code or code segments to perform the necessary tasks will be stored in a machine or computer readable medium such as a storage medium or non-transitory computer readable medium. A processor(s) will perform the necessary tasks.

Specific structural and functional details disclosed herein are merely representative for purposes of describing example embodiments of the present invention. This invention may, however, be embodied in many alternate forms and should not be construed as limited to only the embodiments set forth herein.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments of the present invention. As used herein, the term “and/or,” includes any and all combinations of one or more of the associated listed items.

It will be understood that when an element is referred to as being “connected,” or “coupled,” to another element, it can be directly connected or coupled to the other element or intervening elements may be present. In contrast, when an element is referred to as being “directly connected,” or “directly coupled,” to another element, there are no intervening elements present. Other words used to describe the relationship between elements should be interpreted in a like fashion (e.g., “between,” versus “directly between,” “adjacent,” versus “directly adjacent,” etc.).

The terminology used herein is for the purpose of describing particular embodiments only and is not intended to be limiting of example embodiments of the invention. As used herein, the singular forms “a,” “an,” and “the,” are intended to include the plural forms as well, unless the context clearly indicates otherwise. As used herein, the terms “and/or” and “at least one of” include any and all combinations of one or more of the associated listed items. It will be further understood that the terms “comprises,” “comprising,” “includes,” and/or “including,” when used herein, specify the presence of stated features, integers, steps, operations, elements, and/or components, but do not preclude the presence or addition of one or more other features, integers, steps, operations, elements, components, and/or groups thereof.

It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

Unless otherwise defined, all terms (including technical and scientific terms) used herein have the same meaning as commonly understood by one of ordinary skill in the art to which example embodiments belong. It will be further understood that terms, e.g., those defined in commonly used dictionaries, should be interpreted as having a meaning that is consistent with their meaning in the context of the relevant art and will not be interpreted in an idealized or overly formal sense unless expressly so defined herein.

Portions of the example embodiments and corresponding detailed description may be presented in terms of software, or algorithms and symbolic representations of operation on data bits within a computer memory. These descriptions and representations are the ones by which those of ordinary skill in the art effectively convey the substance of their work to others of ordinary skill in the art. An algorithm, as the term is used here, and as it is used generally, is conceived to be a self-consistent sequence of steps leading to a desired result. The steps are those requiring physical manipulations of physical quantities. Usually, though not necessarily, these quantities take the form of optical, electrical, or magnetic signals capable of being stored, transferred, combined, compared, and otherwise manipulated. It has proven convenient at times, principally for reasons of common usage, to refer to these signals as bits, values, elements, symbols, characters, terms, numbers, or the like.

In the following description, illustrative embodiments may be described with reference to acts and symbolic representations of operations (e.g., in the form of flowcharts) that may be implemented as program modules or functional processes include routines, programs, objects, components, data structures, etc., that perform particular tasks or implement particular abstract data types and may be implemented using existing hardware at existing network elements. Such existing hardware may include one or more Central Processing Units (CPUs), digital signal processors (DSPs), application-specific-integrated-circuits, field programmable gate arrays (FPGAs) computers or the like.

Note also that the software implemented aspects of the example embodiments may be typically encoded on some form of program storage medium or implemented over some type of transmission medium. The program storage medium (e.g., non-transitory storage medium) may be magnetic (e.g., a floppy disk or a hard drive) or optical (e.g., a compact disk read only memory, or “CD ROM”), and may be read only or random access. Similarly, the transmission medium may be twisted wire pairs, coaxial cable, optical fiber, or some other suitable transmission medium known to the art. The example embodiments not limited by these aspects of any given implementation.

It should be borne in mind, however, that all of these and similar terms are to be associated with the appropriate physical quantities and are merely convenient labels applied to these quantities. Unless specifically stated otherwise, or as is apparent from the discussion, terms such as “processing” or “computing” or “calculating” or “determining” of “displaying” or the like, refer to the action and processes of a computer system, or similar electronic computing device/hardware, that manipulates and transforms data represented as physical, electronic quantities within the computer system's registers and memories into other data similarly represented as physical quantities within the computer system memories or registers or other such information storage, transmission or display devices.

Spatially relative terms, such as “beneath”, “below”, “lower”, “above”, “upper”, and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, term such as “below” can encompass both an orientation of above and below. The device may be otherwise oriented (rotated 90 degrees or at other orientations) and the spatially relative descriptors used herein are interpreted accordingly.

Although the terms first, second, etc. may be used herein to describe various elements, components, regions, layers and/or sections, it should be understood that these elements, components, regions, layers and/or sections should not be limited by these terms. These terms are used only to distinguish one element, component, region, layer, or section from another region, layer, or section. Thus, a first element, component, region, layer, or section discussed below could be termed a second element, component, region, layer, or section without departing from the teachings of the present invention.

It is proposed in at least one embodiment that the at least two Positron Emission Tomography detector modules each have a detector surface and the radio frequency antenna unit is disposed outside a region between an examination area and the detector surfaces. In this context an examination region is to be understood especially as a region which comprises a Field of View (FOV) of the Positron Emission Tomography unit and/or a subarea of the patient to be examined in an examination position within a patient receiving area of the medical imaging system. Furthermore the term outside a region disposed between an examination region and the detector surfaces is especially to be understood as a region which is disposed outside an FOV of the Positron Emission Tomography unit, especially outside an FOV of the least to detector modules and/or is disposed outside the patient receiving area.

The inventive embodiment and/or arrangement of the radio frequency antenna unit advantageously enables an undesired attenuation of PET signals during data acquisition to be minimized and/or prevented. Furthermore in this way an especially space-saving and especially compact arrangement of the radio frequency antenna unit together with the PET unit can be achieved. Advantageously in this case the radio frequency antenna unit is disposed in an area adjoining the Positron Emission Tomography detector module, so that an essentially equal and/or overlapping field of view between the radio frequency antenna unit and the Positron Emission Tomography detector module can be achieved. Preferably the radio frequency antenna unit here comprises a radio frequency antenna receive unit which is integrated and/or disposed permanently within the Positron Emission Tomography unit. In this way a position of the radio frequency antenna unit, especially of the radio frequency antenna receive unit, is determined outside a field of view of the Positron Emission Tomography unit.

Furthermore it is proposed that the at least two Positron Emission Tomography detector modules are disposed one after the other along a circumferential direction around the patient receiving area and a gap area of the Positron Emission Tomography unit is disposed between the at least two Positron Emission Tomography detector modules, wherein the radio frequency antenna unit is at least partly disposed within this gap area. The circumferential direction comprises a circumferential direction and/or tangential direction of the patient receiving area, wherein the circumferential direction and/or tangential direction is aligned here essentially around a circular cross-sectional surface of the patient receiving area. Furthermore a gap area is especially to be understood as an area between two Positron Emission Tomography detector modules directly adjacent along the circumferential direction, wherein the gap area preferably has the shape of a prism. The radio frequency antenna unit is able through this arrangement to be disposed in an area of the Positron Emission Tomography detector modules such that the radio frequency antenna unit and the Positron Emission Tomography detector module do not influence each other during an acquisition of image data. The gap area present in any case because of an annular arrangement of the PET detector modules can thus be utilized in an efficient manner and through this an especially compact design of the Positron Emission Tomography detector module and the radio frequency antenna unit is also achieved.

In an advantageous development of at least one embodiment of the invention it is proposed that the at least two Positron Emission Tomography detector modules each have at least one detection-free edge region and the radio frequency antenna unit is disposed at least partly within this detection-free edge region. A detection-free edge region of the Positron Emission Tomography detector module is especially to be understood as a region which is disposed around a detection surface of the Positron Emission Tomography detector module, such as for example a frame of the Positron Emission Tomography detector module. Preferably the detection-free edge area comprises an edge area of the detection surface of the Positron Emission Tomography detector module. In this way an advantageous arrangement of the radio frequency antenna units together with the Positron Emission Tomography detector modules can be achieved, without influencing and/or changing an existing arrangement of the Positron Emission Tomography Detector module of the Positron Emission Tomography detector unit. In addition an installation space previously not effectively used for detection of PET signals can be given an additional use, in that in this edge area magnetic resonance signals are detected by way of the radio frequency antenna unit.

It is further proposed that the Positron Emission Tomography unit has at least one boundary area adjoining the at least two Positron Emission Tomography detector modules, wherein the boundary area is disposed on a side of the Positron Emission Tomography detector module facing away from a detector surface and the radio frequency antenna unit is disposed at least partly within this boundary area adjoining the at least two Positron Emission Tomography detector modules. The radio frequency antenna unit can be disposed especially advantageously outside a detection device of the Positron Emission Tomography detector modules. In addition in this way an undesired adverse effect of a detection of PET signals can be advantageously prevented and thus an attenuation of the PET signals minimized and/or prevented.

It is further proposed in at least one embodiment that the radio frequency antenna unit has at least one antenna element and the at least one antenna element is disposed within the gap area and/or within the edge area and/or within the boundary area. In this context an antenna element is especially to be understood as a conductor track element and/or an electronics element and/or a coolant line element etc., which is encompassed by the radio frequency antenna unit. In this way a distributed arrangement of the individual antenna elements can be achieved, wherein preferably an arrangement and/or a selection of the individual antenna elements are adapted to the installation space available. In addition in this way a planar arrangement of especially conductor track elements can be achieved and thus a planar detection surface and/or acquisition surface and/or transmit surface for acquisition of magnetic resonance signals and/or for transmission of high frequency pulses by way of the radio frequency antenna unit can be achieved.

In a further embodiment of the invention it is proposed that the at least two Positron Emission Tomography detector modules each have a screening housing for detector electronics and the screening housings of the at least two Positron Emission Tomography detector modules are connected into a radio frequency antenna element of the radio frequency antenna unit. In this way the radio frequency antenna unit can be embodied at least partly in one piece with the at least two Positron Emission Tomography detector modules and in this way an especially low-cost and component-saving medical imaging system can be provided. Preferably the radio frequency antenna unit comprises a radio frequency antenna array with a number of radio frequency antenna elements, wherein a number of these radio frequency antenna elements are formed at least partly from screening housings of the Positron Emission Tomography detector modules connected together. In this context a screening housing is especially to be understood as a housing which protects the detector electronics against radio-frequency radiation and/or against being influenced by an applied magnetic field and/or from further adverse effects.

An especially high local resolution during the acquisition of the PET signals can advantageously be achieved if the at least two Positron Emission Tomography detector modules each have a number of Positron Emission Tomography detector elements.

In an advantageous development of at least one embodiment of the invention it is proposed that the radio frequency antenna unit includes a radio frequency antenna receive unit. In this way additional local radio frequency antenna units, such as for example a local head antenna unit and/or a local body antenna unit can advantageously be dispensed with during a combined data acquisition of PET signals and magnetic resonance signals. The magnetic resonance signals are acquired here by way of the radio frequency antenna receive unit.

As an alternative or in addition the radio frequency antenna unit can also include a radio frequency antenna transmit unit, so that the Positron Emission Tomography unit can be integrated in an especially compact way within the magnet unit of the Magnetic Resonance Imaging unit. In addition the radio frequency antenna transmit unit can be embodied in one piece with the radio frequency antenna receive unit.

Furthermore it is also conceivable for the radio frequency antenna transmit unit to be embodied in a conventional manner and to be installed permanently within the magnet unit, wherein the Positron Emission Tomography unit is preferably disposed between the gradient coil unit and the radio frequency antenna transmit unit. As a result of the fixed positioning of the radio frequency antenna transmit unit within the magnet unit a contribution to the attenuation correction for the PET signals is thus consistent and defined. The radio frequency antenna receive unit on the other hand is disposed, in accordance with the inventive embodiment, outside a FOV of the Positron Emission Tomography unit.

In an advantageous development of at least one embodiment of the invention it is proposed that image data of an identical examination area is acquired in each case by way of the radio frequency antenna unit and by way of the Positron Emission Tomography unit. In this way an especially rapid and especially simultaneous acquisition of the magnetic resonance image data and the PET image data can be achieved. In addition in this way a comparability and/or a fusioning between the magnetic resonance image data and the PET image data is possible.

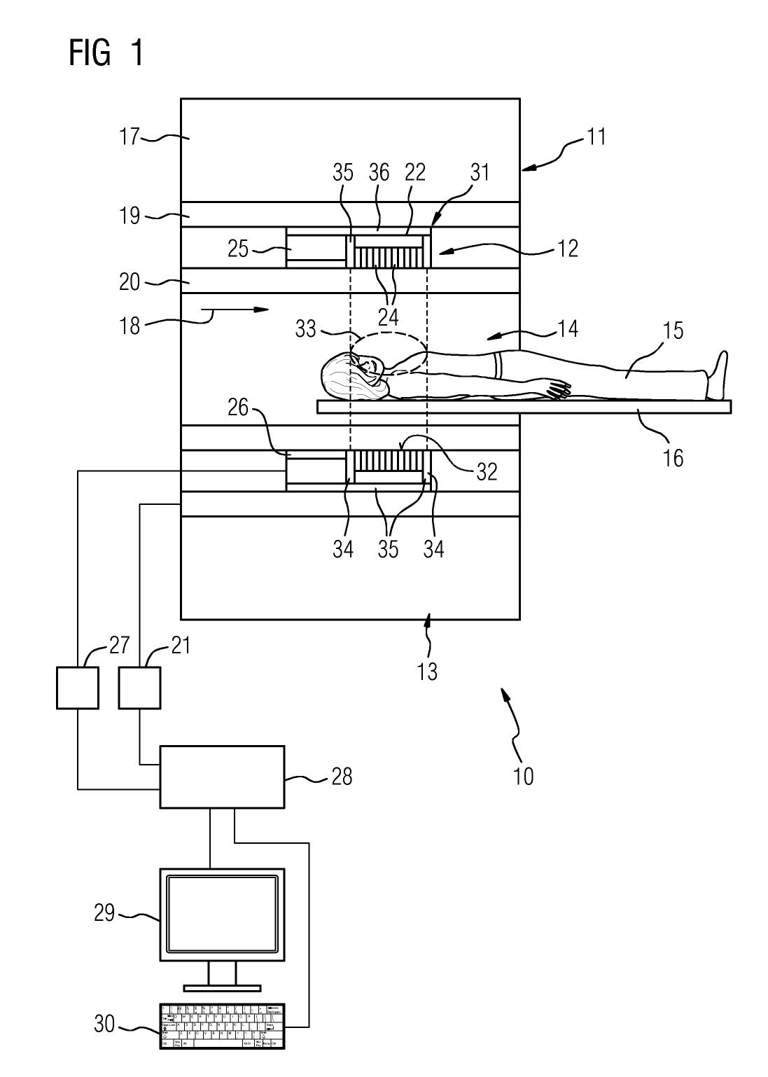

FIG. 1 shows a medical imaging system 10. The medical imaging system 10 is formed by a combined imaging system, which comprises a Magnetic Resonance Imaging unit 11 and a Positron Emission Tomography unit 12 (PET unit 12).

The Magnetic Resonance Imaging unit 11 comprises a magnet unit 13 and a patient receiving area 14 surrounded by the magnet unit 13 for receiving a patient 15, wherein the patient receiving area 14 is surrounded in a circumferential direction 38 by a housing cladding unit of the Magnetic Resonance Imaging unit 11 in a cylindrical shape not shown in any greater detail. The patient 15 can be pushed by way of a patient support facility 16 of the Magnetic Resonance Imaging unit 11 into the patient receiving area 14. The patient support facility 16 is disposed movably within the patient receiving area 14 for this purpose.

The magnet unit 13 comprises a main magnet 17, which is designed during operation of the Magnetic Resonance Imaging unit 11 for generating a strong and especially constant main magnetic field 18. The magnet unit 13 also has a gradient coil unit 19 for generating magnetic field gradients, which are used for location coding during imaging. In addition the magnet unit 13 comprises a first radio-frequency antenna unit 20 which is formed by a radio frequency antenna transmit unit and for exciting a polarization which occurs in the main magnetic field 18 generated by the main magnet 17.

For controlling the main magnet 17 of the gradient coil units 19 and for controlling the radio-frequency antenna unit 20, the medical imaging system 10, especially the Magnetic Resonance Imaging unit 11, has a control unit 21 formed by a processing unit. The control unit 21 centrally controls the Magnetic Resonance Imaging unit 11, such as performing a predetermined imaging gradient echo sequence for example. For this purpose the control unit 21 includes a gradient control unit is not shown in any greater detail and a radio-frequency antenna control unit not shown in any greater detail. In addition the control unit 21 comprises an evaluation unit for evaluation of magnetic resonance image data.

The Magnetic Resonance Imaging unit 11 shown can naturally also include other components which Magnetic Resonance Imaging units 11 normally include. A person skilled in the art also knows how a Magnetic Resonance Imaging unit 11 functions in general, so that a more detailed description of the general components will be dispensed with here.

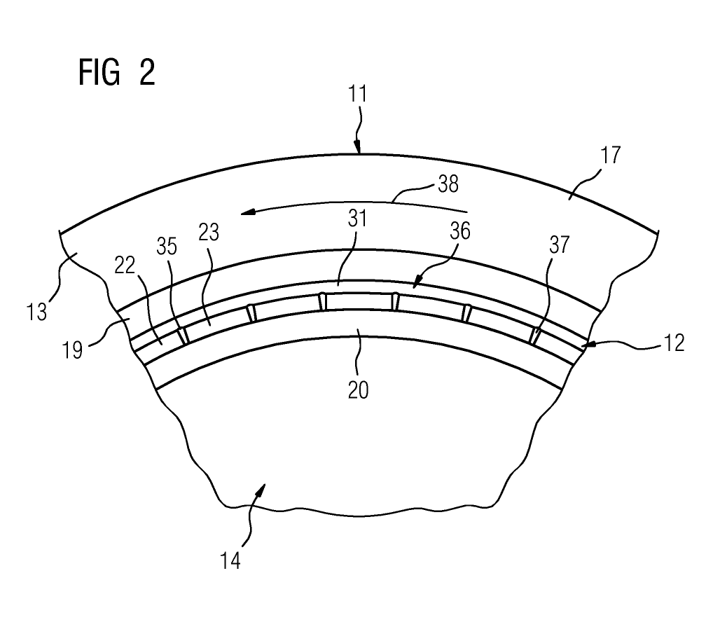

The PET unit 12 comprises a number of Positron Emission Tomography detector modules 22, 23 (PET detector modules), which are arranged in a ring shape and surround the patient receiving area 14 in the circumferential direction 38 (Cf. FIGS. 1 and 2). The PET detector modules 22, 23 each have a number of Positron Emission Tomography detector elements 24 (PET detector elements) which are arranged into a PET detector array which comprises a scintillation detector array with scintillation crystals, for example LSO crystals. Furthermore the PET detector modules 22, 23 each include a photodiode array, for example an avalanche photodiode array or APD photo diode array, which are disposed downstream from the scintillation detector array within the PET detector modules 22, 23.

By way of the PET detector modules 22, 23 photon pairs which result from the annihilation of the positron with an electron, are detected. Trajectories of the two photons enclose an angle of 180°. In addition the two photons each have an energy of 511 keV. The positron is emitted here by a radio pharmaceutical, wherein the radiopharmaceutical is administered via an injection into the patient 15. During passage through material the photons arising during the annihilation can be absorbed, wherein the absorption probability depends on the path length through the material and the corresponding absorption coefficient of the material. Accordingly during an evaluation of the PET signals a correction of these signals in relation to the attenuation through components which are located in the beam path is necessary.

In addition the PET detector modules 22, 23 each have detector electronics 25, comprising an electrical amplifier circuit and further electronic components not shown in any greater detail. Disposed around these detector electronics 25 is a screening housing 26 of the PET detector modules 22, 23 which is embodied impermeable in respect of radio-frequency radiation. This screening housing 26 of the respective PET detector modules 22, 23 is embodied such that essentially no radio-frequency radiation emitted by the radio-frequency antenna unit 20 penetrates the screening housing 26 and can adversely affect the detector electronics 25 and also no radiation emitted by the detector electronics 25, especially in a direction of the patient receiving area 14, can penetrate the screening housing 26 and adversely affect a detection of the radio-frequency radiation.

For control of the detector electronics 25 and the PET detector modules 22, 23 the medical imaging system 10, especially the PET unit 12, has a further control unit 27 formed by a processing unit. The control unit 27 centrally controls the PET unit 12. In addition the control unit 27 comprises an evaluation unit for evaluation of PET data. The PET unit 12 shown can naturally include further components which PET units 12 normally include. A person skilled in the art also knows how a PET unit 12 functions in general, so that a more detailed description of the general components will be dispensed with here.

The medical imaging system also has a central system control unit 28 which for example harmonizes an acquisition of magnetic resonance image data and PET image data with one another. Control information such as imaging parameters for example, and also reconstructed image data, can be displayed on a display unit 29, for example on at least one monitor of the medical imaging system for an operator. In addition the medical imaging system 10 has an input unit 30, by which information and/or parameters can be entered by an operator during a measurement process.

In the present example embodiment the magnet unit 13 of the Magnetic Resonance Imaging unit 11 includes a further radio-frequency antenna unit 31 which is formed by a radio-frequency antenna receive unit and which is designed for receiving a magnetic resonance signals. The radio-frequency antenna receive unit 31 is permanently integrated within the medical imaging system 10.

In order to avoid a disruption and/or undesired interaction between the radio-frequency antenna receive unit and the PET detector modules 22, 23, especially an undesired attenuation of the PET signals, the radio-frequency antenna receive unit is disposed outside an area 33 between an examination area and/or patient receiving area 14 and detector surfaces 32 of the PET detector modules 22, 23. Preferably the radio-frequency antenna receive unit is disposed here in an area adjoining the PET detector modules 22, 23.

The individual PET detector modules 22, 23 each have a detection-free edge area 34 in which for example a frame of the PET detector modules 22, 23, especially around a detector surface 32 of the PET detector array, is disposed. Within this edge area 34 antenna elements 35 of the radio-frequency antenna receive unit are disposed. Preferably the antenna elements 35 disposed in this edge area 34 are formed by conductor track elements and/or by cooling elements, such as for example coolant lines etc. Basically the individual antenna elements 35 can also be formed for example by electronic elements and/or by control elements and/or by further antenna elements 35 appearing sensible to the person skilled in the art.

Furthermore the PET unit 12 has a boundary area 36 adjoining the PET detector modules 22, 23, wherein the boundary area 36 is disposed on a side facing away from the detector surface 32 the PET detector modules 22, 23 and one or more antenna elements 35 of the radio-frequency antenna receive unit 31 are disposed within this boundary area 36 of the PET unit 12.

FIG. 2 shows a cross section through the magnet unit 13 and the PET units 12 of the medical imaging system 10. Disposed along the circumferential direction 38 in each case between two PET detector modules 22, 23 directly adjacent to one another is in each case a gap area 37. This gap area 37 is in the shape of a prism in the present example embodiment with a triangular base surface. As an alternative to this a trapezoidal base surface of the prism shape of the gap area 37 is conceivable, wherein the a shape of the gap area 37 between two directly adjacent PET detector modules 22, 23 is dependent on a spatial embodiment of the PET detector modules 22, 23 and/or further spatial and/or constructional characteristics of the PET detector modules 22, 23 and/or of the magnet unit 13.

Disposed in this gap area 37 are further antenna elements 35 of the radio-frequency antenna unit 31. The individual antenna elements 35 in this gap area 37 are preferably formed by electronics elements. Basically the individual antenna elements 35 can also be formed by conductor track elements and/or cooling components etc.

The arrangement of the high-frequency antenna receive unit around a detection area of the PET detector modules 22, 23, without however adversely affecting a field of view of the PET detector modules 22, 23, advantageously enables an especially compact medical imaging system 10 to be provided, in which an additional and/or undesired attenuation of the PET signals as a result of the radio-frequency antenna receive unit can advantageously be prevented. In addition it is also insured in this way that the radio-frequency antenna receive unit and the PET detector modules 22, 23 each acquire image data, which at least partly covers an identical examination area and/or an identical FOV.

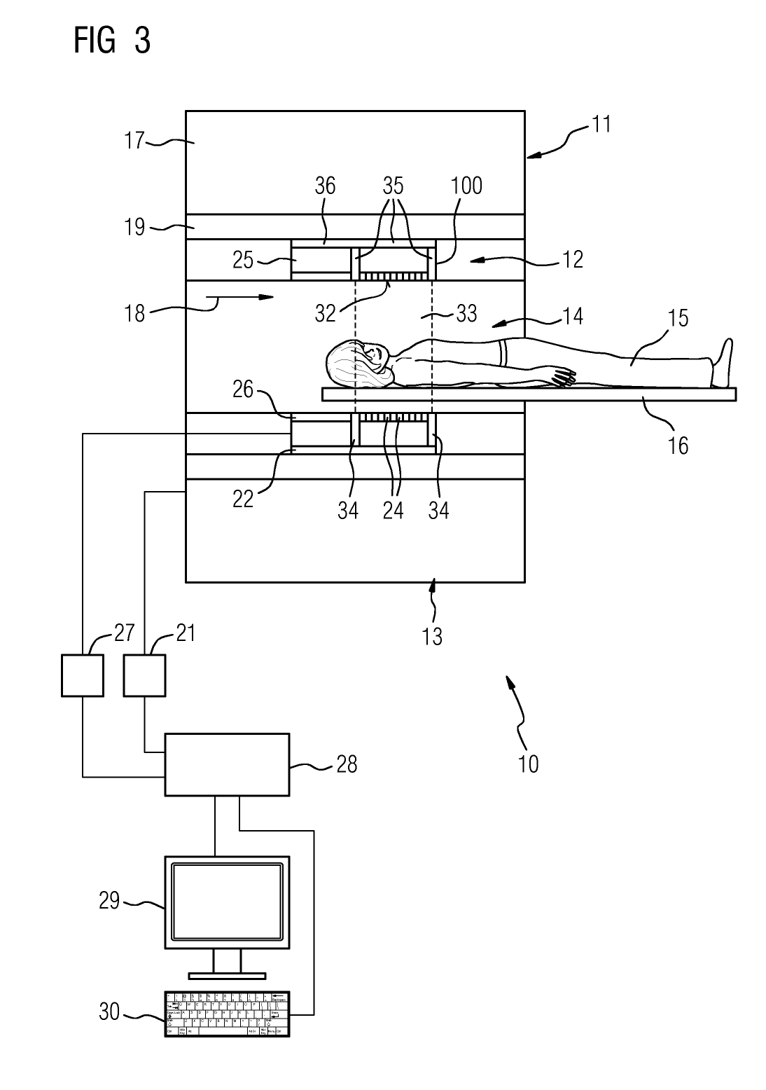

FIG. 3 shows an alternate example embodiment of the medical imaging system 10. Components, features and functions which essentially remain the same are basically labeled with the same reference characters. The description below is restricted essentially to the differences from the example embodiment depicted in FIGS. 1 and 2, wherein as regards components, features and functions which remain the same, the reader is referred to the description of the example embodiment in FIGS. 1 and 2.

The medical imaging system 10 in FIG. 3 likewise comprises a Magnetic Resonance Imaging unit 11 and a PET unit 12. The Magnetic Resonance Imaging unit 11 in FIG. 3 differs from the description for FIGS. 1 and 2 in respect of an embodiment of the radio-frequency antenna unit 100. The Magnetic Resonance Imaging unit 11 in the present example embodiment has a single radio-frequency antenna unit 100, which includes both a radio-frequency antenna receive unit and also a radio-frequency antenna transmit unit, wherein the radio-frequency antenna receive unit and the radio-frequency antenna transmit unit are embodied with one another in one piece. The PET unit 12 together with the radio-frequency antenna unit 100 is disposed here between the patient receiving area 14 and the gradient coil unit 19 of the magnet unit 13.

An arrangement of the radio-frequency antenna unit 100 within the medical imaging system 10, especially within the PET unit 12, corresponds to an arrangement of the radio-frequency antenna receive unit within the PET units 12 in FIGS. 1 and 2. Accordingly the radio frequency antenna unit 100 in FIG. 3 is also disposed outside an area 33 disposed between an examination area and the detector surfaces 32 of the PET detector modules 22, 23.

The radio-frequency antenna units 31, 100 of FIGS. 1 and 3, especially the antenna elements 35 of the radio-frequency antenna units 31, 100, can also only be disposed within the gap area 37 between two directly adjacent PET detector modules 22, 23 or also only within the detection-free edge area 34 of the PET detector modules 22, 23. As an alternative to this an arrangement of the antenna elements 35 of the radio-frequency antenna units 31, 100 only within the boundary area 36 adjoining the PET detector modules is conceivable. Basically any given combination of the arrangement of the antenna elements 35 of the radio-frequency antenna units 31, 100 within the gap area 37 and/or the detection-free edge area 34 and/or within the boundary area 36 is also conceivable.

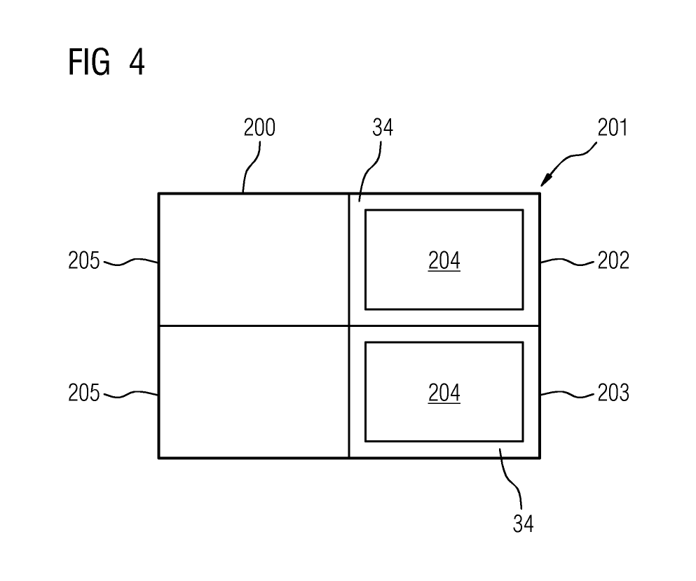

FIG. 4 shows a further alternate example embodiment of an arrangement of a radio frequency antenna unit 200 of the medical imaging system 10. Components, features and functions which essentially remain the same are basically labeled with the same reference characters. The description given below is restricted essentially to the differences from the example embodiment in FIGS. 1 to 3 wherein, as regards components, features and functions which remain the same, the reader is referred to the description of the example embodiment in FIGS. 1 to 3.

In FIG. 4 the PET unit 201 is shown by way of example with only two PET detector modules 202, 203. The PET detector modules 202, 203 are shown in a view onto the detector surfaces 204. The individual screening housings 205 for detector electronics of the PET detector modules are connected in the present example embodiment to the radio-frequency antenna unit 200 of the magnet unit 13. Preferably the single screening housing 205 is connected here to conductor track elements for receiving and/or transmitting the radio-frequency signals. Preferably the radio-frequency antenna unit 200 comprises a radio-frequency antenna array with a number of antenna elements 35, wherein several of these antenna elements 35 are formed at least partly by interconnected screening housings 205 of the PET detector modules 202, 203. Further radio frequency antenna electronics and/or a cooling of the radio-frequency antenna units 200 can additionally be disposed in a gap area between two adjacent PET detector modules 202, 203 and/or in a boundary area adjoining the PET detector modules 202, 203, as is described by way of example in FIGS. 1 and 2.

The radio-frequency antenna units 200 can include both a radio-frequency antenna receive unit and also a radio-frequency antenna transmit unit. A further embodiment of the PET units 12 and/or of the radio-frequency antenna unit 200 corresponds to the description given for FIGS. 1 to 3. In particular the radio-frequency antenna unit 200 can be embodied in accordance with FIGS. 1 to 2 and only have one radio-frequency antenna receive unit. Furthermore the radio-frequency antenna unit 200 can also be embodied in accordance with FIG. 3 and have a radio-frequency antenna receive unit together with a radio-frequency antenna transmit unit.

The screening housing 205 connected to conductor track elements of the radio-frequency antenna unit 200 can also be combined with an arrangement of further antenna elements of the radio-frequency antenna unit 200, as described in FIGS. 1 to 3. Accordingly an additional arrangement of antenna elements of the radio frequency antenna unit 200 within the gap area 37 between two PET detector modules 202, 203 directly adjoining one another and/or within a detection-free edge area 34 of the PET detector modules 202, 203 is possible. Furthermore an arrangement of further antenna elements of the radio-frequency antenna unit 200 within a boundary area 36 adjoining the PET detector modules 202, 203 is also possible.

The patent claims filed with the application are formulation proposals without prejudice for obtaining more extensive patent protection. The applicant reserves the right to claim even further combinations of features previously disclosed only in the description and/or drawings.

The example embodiment or each example embodiment should not be understood as a restriction of the invention. Rather, numerous variations and modifications are possible in the context of the present disclosure, in particular those variants and combinations which can be inferred by the person skilled in the art with regard to achieving the object for example by combination or modification of individual features or elements or method steps that are described in connection with the general or specific part of the description and are contained in the claims and/or the drawings, and, by way of combinable features, lead to a new subject matter or to new method steps or sequences of method steps, including insofar as they concern production, testing and operating methods.

References back that are used in dependent claims indicate the further embodiment of the subject matter of the main claim by way of the features of the respective dependent claim; they should not be understood as dispensing with obtaining independent protection of the subject matter for the combinations of features in the referred-back dependent claims. Furthermore, with regard to interpreting the claims, where a feature is concretized in more specific detail in a subordinate claim, it should be assumed that such a restriction is not present in the respective preceding claims.

Since the subject matter of the dependent claims in relation to the prior art on the priority date may form separate and independent inventions, the applicant reserves the right to make them the subject matter of independent claims or divisional declarations. They may furthermore also contain independent inventions which have a configuration that is independent of the subject matters of the preceding dependent claims.

Further, elements and/or features of different example embodiments may be combined with each other and/or substituted for each other within the scope of this disclosure and appended claims.

Still further, any one of the above-described and other example features of the present invention may be embodied in the form of an apparatus, method, system, computer program, tangible computer readable medium and tangible computer program product. For example, of the aforementioned methods may be embodied in the form of a system or device, including, but not limited to, any of the structure for performing the methodology illustrated in the drawings.

Even further, any of the aforementioned methods may be embodied in the form of a program. The program may be stored on a tangible computer readable medium and is adapted to perform any one of the aforementioned methods when run on a computer device (a device including a processor). Thus, the tangible storage medium or tangible computer readable medium, is adapted to store information and is adapted to interact with a data processing facility or computer device to execute the program of any of the above mentioned embodiments and/or to perform the method of any of the above mentioned embodiments.

The tangible computer readable medium or tangible storage medium may be a built-in medium installed inside a computer device main body or a removable tangible medium arranged so that it can be separated from the computer device main body. Examples of the built-in tangible medium include, but are not limited to, rewriteable non-volatile memories, such as ROMs and flash memories, and hard disks. Examples of the removable tangible medium include, but are not limited to, optical storage media such as CD-ROMs and DVDs; magneto-optical storage media, such as MOs; magnetism storage media, including but not limited to floppy disks (trademark), cassette tapes, and removable hard disks; media with a built-in rewriteable non-volatile memory, including but not limited to memory cards; and media with a built-in ROM, including but not limited to ROM cassettes; etc. Furthermore, various information regarding stored images, for example, property information, may be stored in any other form, or it may be provided in other ways.

Although the invention has been illustrated and described in greater detail by the preferred example embodiment, the invention is not restricted by these disclosed examples and other variations can be derived therefrom by the person skilled in the art, without departing from the scope of the invention.

What is claimed is:

1. A medical imaging system, comprising:
a magnetic resonance imaging unit including
a magnet unit and
a patient receiving area surrounded by the magnet unit, wherein the magnet unit includes a main magnet,
a gradient coil unit and a radio-frequency antenna unit; and
a positron emission tomography unit including
at least two positron emission tomography detector modules, the at least two positron emission tomography detector modules each including a detector surface, the radio-frequency antenna unit being disposed outside an area disposed between an examination area and the detector surfaces.

2. The medical imaging system of claim 1, wherein the at least two positron emission tomography detector modules are disposed after one another in a circumferential direction around the patient receiving area, wherein a gap area is disposed between the at least two positron emission tomography detector modules, and wherein the radio-frequency antenna unit is disposed at least partly within the gap area.

3. The medical imaging system of claim 1, wherein the at least two positron emission tomography detector modules each include a detection-free edge area and wherein the radio-frequency antenna unit is disposed at least partly within the detection-free edge area.

4. The medical imaging system of claim 1, wherein the positron emission tomography unit includes at least one boundary area adjoining the at least two positron emission tomography detector modules, wherein the boundary area is disposed on a side of the positron emission tomography detector modules facing away from a detector surface and wherein the radio-frequency antenna unit is disposed at least partly within the boundary area adjoining the at least two positron emission tomography detector modules.

5. The medical imaging system of claim 2, wherein the radio-frequency antenna unit includes at least one antenna element and wherein the at least one antenna element is disposed within at least one of the gap area, the edge area and the boundary area.

6. The medical imaging system of claim 1, wherein the at least two positron emission tomography detector modules each include a screening housing for detector electronics and wherein the screening housings of the at least two positron emission tomography detector modules are connected to an antenna element of the radio-frequency antenna unit.

7. The medical imaging system of claim 1, wherein the at least two positron emission tomography detector modules each include a number of Positron Emission Tomography detector elements.

8. The medical imaging system of claim 1, wherein the radio-frequency antenna unit includes a radio-frequency antenna receive unit.

9. The medical imaging system of claim 1, wherein the radio-frequency antenna unit includes a radio-frequency transmit unit.

10. The medical imaging system of claim 1, wherein image data of an identical examination area is acquired, in each case, via the respective radio-frequency antenna unit and via a respective positron emission tomography unit.

11. The medical imaging system of claim 3, wherein the radio-frequency antenna unit includes at least one antenna element and wherein the at least one antenna element is disposed within at least one of the gap area, the edge area and the boundary area.

12. The medical imaging system of claim 4, wherein the radio-frequency antenna unit includes at least one antenna element and wherein the at least one antenna element is disposed within at least one of the gap area, the edge area and the boundary area.

13. The medical imaging system of claim 2, wherein the at least two positron emission tomography detector modules each include a screening housing for detector electronics and wherein the screening housings of the at least two positron emission tomography detector modules are connected to an antenna element of the radio-frequency antenna unit.

14. The medical imaging system of claim 2, wherein the at least two positron emission tomography detector modules each include a number of Positron Emission Tomography detector elements.

15. The medical imaging system of claim 2, wherein the radio-frequency antenna unit includes a radio-frequency antenna receive unit.

16. The medical imaging system of claim 2, wherein the radio-frequency antenna unit includes a radio-frequency transmit unit.

17. The medical imaging system of claim 2, wherein image data of an identical examination area is acquired, in each case, via the respective radio-frequency antenna unit and via a respective positron emission tomography unit.
